(19) United States
(12) Patent Application Publication
(10) Pub. No.: US 2025/0280639 A1
(43) Pub. Date: Sep. 4, 2025

(54) DISPLAY DEVICE AND METHOD FOR MANUFACTURING DISPLAY DEVICE

(71) Applicant: Samsung Display Co., LTD., Yongin-si (KR)

(72) Inventors: Won Ho LEE, Yongin-si (KR); Ki Bum KIM, Yongin-si (KR); Tae Gyun KIM, Yongin-si (KR)

(73) Assignee: Samsung Display Co., LTD., Yongin-si (KR)

(21) Appl. No.: 18/984,247

(22) Filed: Dec. 17, 2024

(30) Foreign Application Priority Data
Mar. 4, 2024 (KR) 10-2024-0030432

(51) Int. Cl. H10H 29/39; H10H 29/01; H10H 29/856

(52) U.S. Cl. CPC H10H 29/39; H10H 29/012; H10H 29/856

(57) ABSTRACT

A display device including a substrate including a pixel circuit, a pixel electrode connected to the pixel circuit, an insulating layer disposed on the pixel electrode, a through electrode penetrating the insulating layer and connecting to the pixel electrode, a bottom bonding electrode and an upper bonding electrode sequentially disposed on the through electrode and the insulating layer, and a light emitting element disposed on the upper bonding electrode. The through electrode has a groove whose upper surface is concave downward. A lower surface of the bottom bonding electrode follows the surface profile of the insulating layer and the through electrode disposed below, and an upper surface is flat. The bottom bonding electrode includes an oxide layer.

### CROSS-REFERENCE TO RELATED APPLICATION(S)

This application claims priority to and benefits of Korean Patent Application No. 10-2024-0030432 under 35 U.S.C. § 119, filed on Mar. 4, 2024 in the Korean Intellectual Property Office, the entire contents of which are incorporated herein by reference.

### BACKGROUND

### 1. Technical Field

This disclosure relates to a display device and a method for manufacturing the same.

### 2. Description of the Related Art

The importance of display devices is gradually increasing along with the development of multimedia. In response, various display devices such as liquid crystal display devices and light emitting display devices are being developed. Among these, light emitting display devices may include a display panel including light emitting elements. Display panels may be applied to various types of electronic devices, including portable electronic devices and televisions, as well as virtual reality (VR) devices and augmented reality (AR) devices.

Aspects and features of embodiments of the disclosure are to provide a method of manufacturing a display device that may increase the manufacturing efficiency of a display panel including light emitting elements.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

According to embodiments, a display device and a method for manufacturing a display device that minimize disconnection between a pixel electrode and a light emitting element may be provided.

However, aspects of the disclosure are not restricted to the one set forth herein. The above and other aspects of the disclosure will become more apparent to one of ordinary skill in the art to which the disclosure pertains by referencing the detailed description of the disclosure given below.

According to an embodiment, a display device may include a substrate including a pixel circuit, a pixel electrode connected to the pixel circuit, an insulating layer disposed on the pixel electrode, a through electrode penetrating the insulating layer and connecting to the pixel electrode, a bottom bonding electrode and an upper bonding electrode sequentially disposed on the through electrode and the insulating layer; and a light emitting element disposed on the upper bonding electrode. The through electrode may have a groove whose upper surface is concave downward. A lower surface of the bottom bonding electrode may follow a surface profile of the insulating layer and the through electrode disposed below, and the upper surface is flat. The bottom bonding electrode may have an oxide layer between layers.

In an embodiment, the lower surface of the bottom bonding electrode may have a downwardly convex protrusion corresponding to a concave groove of the through electrode, and the upper surface may be flat.

In an embodiment, the bottom bonding electrode may include a first bottom bonding electrode formed of different materials and a second bottom bonding electrode disposed on the first bottom bonding electrode. The oxide layer may be disposed between layers of the first bottom bonding electrode.

In an embodiment, the first bottom bonding electrode and the second bottom bonding electrode may be made of a material selected from the group consisting of titanium (Ti), nickel (Ni), platinum (Pt), tin (Sn), gold (Au), aluminum (Al), and tungsten (W).

In an embodiment, an upper surface and a lower surface of the upper bonding electrode may be flat.

In an embodiment, the upper bonding electrode may be formed of one or more layers.

In an embodiment, the display device may further include a barrier film surrounding a side surface of the through electrode.

In an embodiment, the barrier film may include a material that prevents movement of metal ions forming the through electrode.

In an embodiment, the upper connection bonding electrode and the bottom connection bonding electrode may protrude outside the light emitting element.

In an embodiment, the display device may further include a first insulating layer that surrounds sides of the light emitting element and the upper bonding electrode, a reflective layer disposed on a side of the light emitting element, a second insulating layer surrounding sides of the light emitting element and the upper bonding electrode on the reflective layer and the first insulating layer and a common electrode disposed on an upper portion of the light emitting element.

In an embodiment, the display device may further include a lens-type optical structure on a light emitting element layer including the light emitting element and the common electrode.

According to an embodiment, a method of manufacturing a display device may include providing a backplane substrate including a pixel electrode connected to a pixel circuit and an insulating layer disposed on the pixel electrode, forming a through electrode that penetrates the insulating layer and is connected to the pixel electrode, planarizing top surfaces of the insulating layer and the through electrode, applying a conductive bonding material to a top surface of the through electrode, planarizing the conductive bonding material to form an oxide layer on the top surface of the through electrode, forming a bottom bonding electrode layer by additionally applying a conductive bonding material on a conductive bonding material on which the oxide layer is formed, providing a base substrate having an upper bonding electrode layer and a plurality of semiconductor layers, bonding the base substrate and the backplane substrate and removing the base substrate and forming a plurality of light emitting elements by etching the plurality of semiconductor layers.

In an embodiment, the planarizing of the top surfaces of the insulating layer and the through electrode, the planarizing of the conductive bonding material to form an oxide layer on the top surface of the through electrode, and the removing of the base substrate may include a chemical mechanical polishing (CMP) process.

In an embodiment, the planarizing of the top surfaces of the insulating layer and the through electrode may include forming a downwardly concave groove on the through electrode.

In an embodiment, a lower surface of the bottom bonding electrode layer may have a downwardly convex protrusion corresponding to a concave groove of the through electrode, and an upper surface of the bottom bonding electrode may be flat.

In an embodiment, the method may further include forming a bonding electrode by etching the bottom bonding electrode layer and the upper bonding electrode layer.

In an embodiment, the forming of the bottom bonding electrode layer may include additionally applying a conductive bonding material on the conductive bonding material on which the oxide layer is formed, forming a first bottom bonding electrode layer by additionally applying the first conductive bonding material, and forming a second bottom bonding electrode layer on the first bottom bonding electrode layer by applying a second conductive bonding material different from the first conductive bonding material.

In an embodiment, the method may further include forming an insulating layer and a reflective layer surrounding a side surface of the light emitting element.

In an embodiment, the method may further include forming a common electrode on the light emitting elements.

In an embodiment, the method may further include forming a lens-type optical structure on the light emitting element layer including the light emitting elements and the common electrode.

Accordingly, the manufacturing efficiency of a display panel including light emitting elements and a display device including the same may be increased and yield improved.

However, the effects of the disclosure are not limited to the aforementioned effects, and various other effects are included in the specification.

### BRIEF DESCRIPTION OF THE DRAWINGS

The above and other aspects and features of the disclosure will become more apparent by describing in detail embodiments thereof with reference to the attached drawings, in which:

FIG. 1 is a schematic perspective view illustrating a display device according to one embodiment.

FIG. 2 is a schematic plan view illustrating one embodiment of area A of FIG. 1.

FIG. 3 is a schematic cross-sectional view illustrating one embodiment of a cross-section of the display panel corresponding to the lines X1-X1′ in FIG. 2.

FIG. 4 is an enlarged schematic cross-sectional view illustrating an example of the insulating layer and through electrode of FIG. 3.

FIG. 5 is an enlarged schematic cross-sectional view illustrating an example of the insulating layer, through electrode, and bonding electrode of FIG. 3.

FIG. 6 is an enlarged schematic cross-sectional view illustrating another example of the insulating layer and through electrode of FIG. 4.

FIG. 7 is a schematic cross-sectional view illustrating a light emitting element according to one embodiment.

FIG. 8 is a flowchart illustrating a manufacturing method of a display device according to one embodiment.

FIGS. 9 to 25 are schematic diagrams to illustrate a method of manufacturing a display panel according to one embodiment.

FIG. 26 is a schematic cross-sectional view to illustrate a void that may occur in case that a planarization process is not performed on a bottom bonding electrode.

FIG. 27 is a schematic diagram showing a virtual reality device including a display device according to an embodiment.

FIG. 28 is a schematic diagram showing a smart device including a display device according to an embodiment.

FIG. 29 is a schematic diagram of an example schematically showing a vehicle including a display device according to an embodiment.

FIG. 30 is a schematic diagram of an example schematically showing a transparent display device including a display device according to an embodiment.

### DETAILED DESCRIPTION OF THE EMBODIMENTS

The embodiments will now be described more fully hereinafter with reference to the accompanying drawings. The embodiments may, however, be provided in different forms and should not be construed as limiting. The same reference numbers indicate the same components throughout the disclosure. In the accompanying figures, the thickness of layers and regions may be exaggerated for clarity.

Some of the parts which are not associated with the description may not be provided in order to describe embodiments of the disclosure.

It will also be understood that when a layer is referred to as being “on” another layer or substrate, it can be directly on the other layer or substrate, or intervening layers may also be present. In contrast, when an element is referred to as being “directly on” another element, there may be no intervening elements present.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

The spatially relative terms “below,” “beneath,” “lower,” “above,” “upper,” or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

When an element is referred to as being “connected” or “coupled” to another element, the element may be “directly connected” or “directly coupled” to another element, or “electrically connected” or “electrically coupled” to another element with one or more intervening elements interposed therebetween. It will be further understood that when the terms “comprises,” “comprising,” “has,” “have,” “having,” “includes” and/or “including” are used, they may specify the presence of stated features, integers, steps, operations, elements and/or components, but do not preclude the presence or addition of other features, integers, steps, operations, elements, components, and/or any combination thereof.

It will be understood that, although the terms “first,” “second,” “third,” or the like may be used herein to describe various elements, these elements should not be limited by these terms. These terms are used to distinguish one element from another element or for the convenience of description and explanation thereof. For example, when “a first element” is discussed in the description, it may be termed “a second element” or “a third element,” and “a second element” and “a third element” may be termed in a similar manner without departing from the teachings herein.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within +30%, 20%, 10%, 5% of the stated value.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.” In the specification and the claims, the phrase “at least one of” is intended to include the meaning of “at least one selected from the group of” for the purpose of its meaning and interpretation. For example, “at least one of A and B” may be understood to mean “A, B, or A and B.”

Unless otherwise defined or implied, all terms used herein (including technical and scientific terms) have the same meaning as commonly understood by those skilled in the art to which this disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

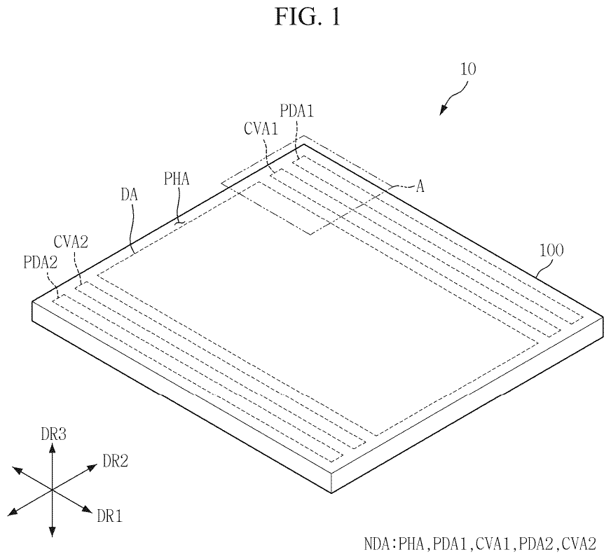

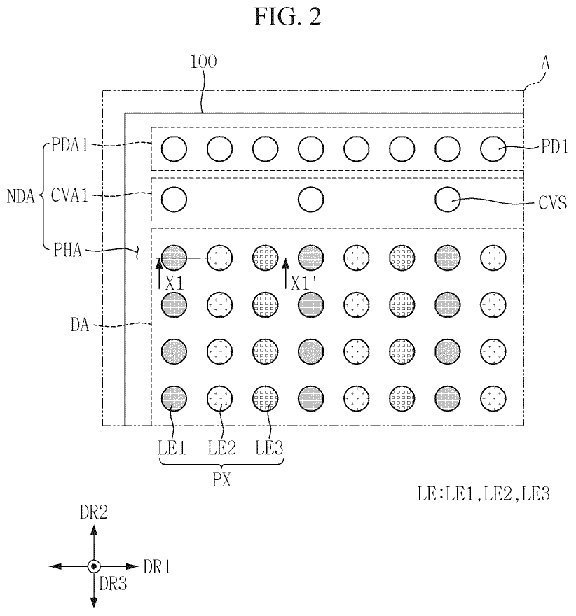

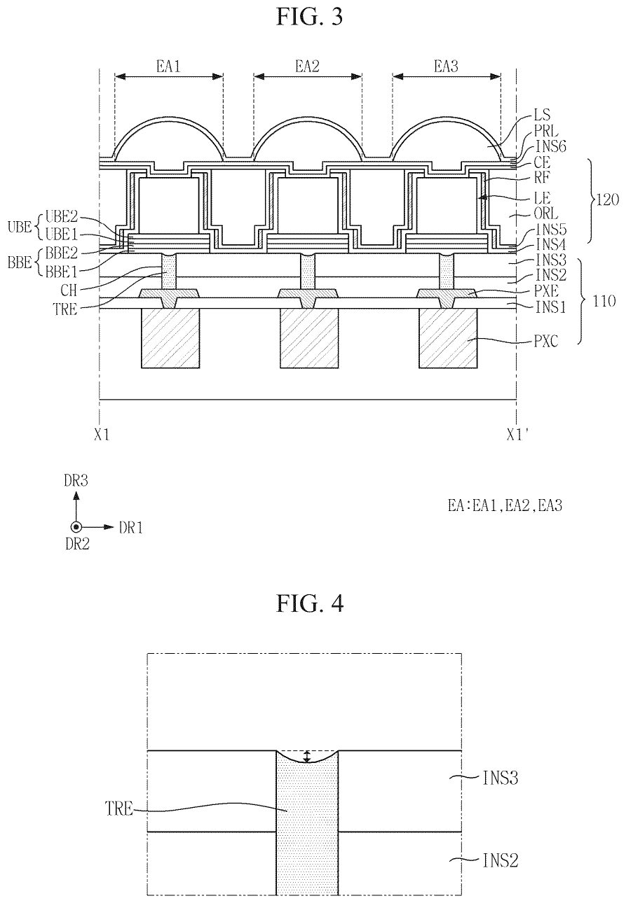

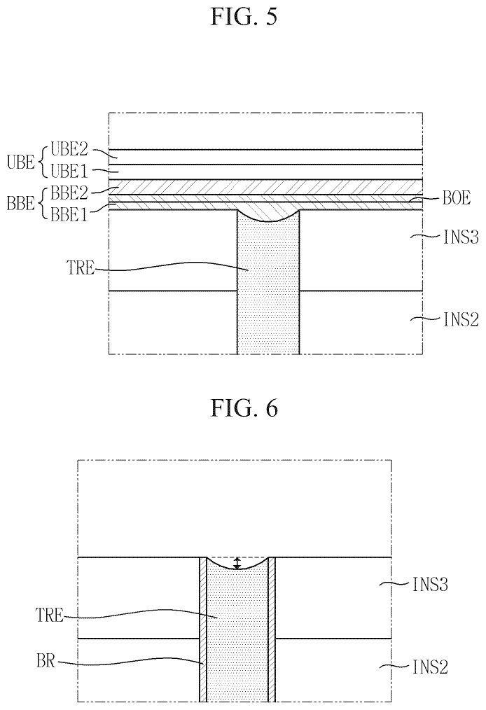

FIG. 1 is a schematic perspective view illustrating a display device according to one embodiment. FIG. 2 is a schematic plan view illustrating one embodiment of area A of FIG. 1. FIG. 3 is a schematic cross-sectional view illustrating one embodiment of a cross-section of the display panel corresponding to the lines X1-X1′ in FIG. 2. FIG. 4 is an enlarged schematic cross-sectional view illustrating an example of the insulating layer and through electrode of FIG. 3. FIG. 5 is an enlarged schematic cross-sectional view illustrating an example of the insulating layer, through electrode, and bonding electrode of FIG. 3.

FIGS. 1 to 3 illustrate an embodiment in which the display device 10 is an LEDoS (Light Emitting Diode on Silicon) in which light emitting diodes are disposed as light emitting elements LE on a semiconductor circuit board formed by a semiconductor process using a silicon wafer (e.g., a backplane substrate 110 of the display panel 100 on which a pixel circuit PXC or the like is formed based on a silicon wafer). However, devices including light emitting elements LE according to embodiments are not limited thereto. For example, the light emitting elements LE manufactured according to embodiments may be applied to display devices of different types and/or structures or may be applied to devices of different types and/or structures, such as lighting devices, etc. As one example, the embodiments described with reference to FIGS. 4 to 19 may also be applied to manufacturing devices of other types and/or structures including light emitting elements LE.

In FIGS. 1 to 3, the first direction DR1 may indicate a horizontal direction of the display panel 100, and the second direction DR2 may indicate a vertical direction of the display panel 100. The third direction DR3 may indicate a thickness direction of the display panel 100.

Referring to FIGS. 1 and 2, the display device 10 according to one embodiment may include a display panel 100 including a display area DA and a non-display area NDA.

The display panel 100 may have a rectangular planar shape with a long side in the first direction DR1 and a short side in the second direction DR2. However, the planar shape of the display panel 100 is not limited to this, and the display panel 100 may have another shape. For example, the display panel 100 may have a polygonal, circular, elliptical, or other non-rectangular planar shape other than a rectangular shape.

The display area DA may be an area where an image is displayed, and the non-display area NDA may be an area where the image is not displayed. In one embodiment, the planar shape of the display area DA may follow the planar shape of the display panel 100. In FIG. 1, the planar shape of the display area DA is illustrated as a rectangle. The display area DA may be disposed in the central area of the display panel 100. The non-display area NDA may be disposed around the display area DA. In one example, the non-display area NDA may surround the display area DA.

The display area DA may include pixels PX. Each pixel PX may include at least two light emitting elements LE.

In one embodiment, each pixel PX may include three light emitting elements LE. For example, each pixel PX may include a first light emitting element LE1, a second light emitting element LE2, and a third light emitting element LE3. The number and/or type of light emitting elements LE provided to the pixels PX may be varied in different embodiments.

In one embodiment, each pixel PX may include light emitting elements LE that emit light of different colors. For example, the first light emitting element LE1, the second light emitting element LE2, and the third light emitting element LE3 may emit light of different colors.

The first light emitting element LE1 may emit a first light. The first light may be red light. For example, the main peak wavelength (R-peak) of the first light may be located at approximately 600 nm to approximately 750 nm, but embodiments are not limited thereto.

The second light emitting element LE2 may emit a second light. The second light may be green light. For example, the main peak wavelength (G-peak) of the second light may be located at approximately 480 nm to approximately 560 nm, but embodiments are not limited thereto.

The third light emitting element LE3 may emit a third light. The third light may be blue light. For example, the main peak wavelength (B-peak) of the third light may be located at approximately 370 nm to approximately 460 nm, but embodiments are not limited thereto.

In another embodiment, the first light emitting element LE1, the second light emitting element LE2, and the third light emitting element LE3 may emit light of the same color as each other. A light conversion layer including a light conversion element (e.g., a quantum dot) for converting the color of light (or a wavelength band corresponding thereto) emitted from the at least one light emitting element LE into light of another color (or a wavelength band corresponding thereto) may be disposed on at least one light emitting element LE among the first light emitting element LE1, the second light emitting element LE2, and the third light emitting element LE3, the color of light emitted from the at least one light emitting element LE.

In one embodiment, the first light emitting element LE1, the second light emitting element LE2, and the third light emitting element LE3 of each pixel PX may be sequentially disposed in the first direction DR1. In one embodiment, the first light emitting elements LE1 may be arranged in the second direction DR2. The second light emitting elements LE2 may be arranged in the second direction DR2. The third light emitting elements LE3 may be arranged in the second direction DR2. For example, in each pixel column extending along the second direction DR2, the first light emitting element LE1, the second light emitting element LE2, or the third light emitting element LE3 may be arranged. In addition, the pixels PX, and the arrangement structure of the light emitting elements LE provided in the pixels PX, may be varied in different embodiments.

In one embodiment, the light emitting elements LE may be arranged in the display area DA at substantially equal intervals but embodiments are not limited thereto. For example, the positions and/or array spacing of the light emitting elements LE may be varied depending on the embodiments.

In one embodiment, the sizes (e.g., areas) of the light emitting elements LE may be substantially the same as each other. For example, the first light emitting element LE1, the second light emitting element LE2, and the third light emitting element LE3 may have substantially the same size. However, the embodiments are not limited to this, and the size of each light emitting element LE and/or the area of the light emitting areas corresponding to the light emitting elements LE may be varied in different embodiments.

In one embodiment, the light emitting elements LE may have a circular planar shape, but the embodiments are not limited thereto. For example, the light emitting elements LE may have a rectangular shape or another polygonal shape, an elliptical shape, or any other polygonal, elliptical, or irregular shape. Further, the light emitting elements LE may have substantially the same planar shape as each other or may have different planar shapes for each group.

The non-display area NDA may include a first common voltage supply area CVA1, a second common voltage supply area CVA2, a first pad area PDA1, a second pad area PDA2, and a peripheral area PHA.

The first common voltage supply area CVA1 may be disposed between the first pad area PDA1 and the display area DA. The second common voltage supply area CVA2 may be disposed between the second pad area PDA2 and the display area DA. Each of the first common voltage supply area CVA1 and the second common voltage supply area CVA2 may include common electrode connecting portions CVS connected to a common electrode (e.g., common electrode CE in FIG. 3). For example, the common electrode may extend from the display area DA to the first common voltage supply area CVA1 and the second common voltage supply area CVA2 and may be electrically connected to the common electrode connecting portions CVS. A common voltage may be supplied to the common electrode through common electrode connecting portions CVS.

The common electrode connecting portions CVS may be disposed in a common voltage supply area (e.g., the first common voltage supply area CVA1 and/or the second common voltage supply area CVA2) of the non-display area NDA. The common electrode connecting portions CVS may include a conductive material (e.g., a metal material such as aluminum (Al)). While FIGS. 1 and 2 illustrate the display device 10 in which the common electrode connecting portions CVS are disposed in the non-display area NDA, the embodiments are not limited thereto. For example, the common electrode connecting portions CVS may be disposed in the display area DA. In one example, the common electrode connecting portions CVS may be disposed in pixel areas or between pixel areas.

The common electrode connecting portions CVS of the first common voltage supply area CVA1 may be electrically connected to one of the first pads PD1 of the first pad area PDA1. For example, the common electrode connecting portions CVS of the first common voltage supply area CVA1 may be supplied with a common voltage from one of the first pads PD1 of the first pad area PDA1.

The first pads PD1 may be disposed in the first pad area PDA1. The first pads PD1 may be connected to a circuit board (not shown) through a conductive connection member. For example, the first pads PD1 may be electrically connected to a circuit pad provided on a circuit board through wires.

The common electrode connecting portions CVS of the second common voltage supply area CVA2 may be electrically connected to one of the second pads of the second pad area PDA2. For example, the common electrode connecting portions CVS of the second common voltage supply area CVA2 may be supplied with a common voltage from one of the second pads of the second pad area PDA2. In one embodiment, the display panel 100 may not include the second common voltage supply area CVA2.

The first pad area PDA1 may be disposed on a side (e.g., the upper side) of the display panel 100. The first pad area PDA1 may include first pads PD1 connected to an external circuit board.

The second pad area PDA2 may be disposed on another side (e.g., the lower side) of the display panel 100. The second pad area PDA2 may include second pads connected to an external circuit board. In one embodiment, the display panel 100 may not include the second pad area PDA2.

The second pads may be disposed in the second pad area PDA2 of the non-display area NDA. The second pads may be connected to the circuit board (not shown) through a conductive connection member. For example, the second pads may be electrically connected to circuit pads provided on the circuit board through wires.

The peripheral area PHA may be the non-display area NDA excluding the first common voltage supply area CVA1, the second common voltage supply area CVA2, the first pad area PDA1, and the second pad area PDA2. The peripheral area PHA may surround the display area DA, as well as the first common voltage supply area CVA1, the second common voltage supply area CVA2, the first pad area PDA1, and the second pad area PDA2.

Referring to FIG. 3, the display panel 100 may include a backplane substrate 110 and a light emitting element layer 120. In one embodiment, the display panel 100 may further include an optical structure (or light emitting structure) provided on the light emitting element layer 120, for example, a lens-type optical structure LS.

The display panel 100 may further include additional components according to embodiments. For example, the display panel 100 may further include a light conversion layer for converting the color and/or wavelength of light emitted from at least some of the light emitting elements LE, and/or a color filter layer for controlling that light of a particular color is emitted from each of the light emitting areas EA.

The display panel 100 may include light emitting areas EA located in the display area DA. Each of the light emitting areas EA may include at least one light emitting element LE. For example, the light emitting areas EA may include a first light emitting area EA1 provided with at least one first light emitting element LE1 and a second light emitting area EA2 provided with at least one second light emitting element LE2, and a third light emitting area EA3 provided with at least one third light emitting element LE3. In one embodiment, first light, second light, and third light may be emitted from the first light emitting area EA1, the second light emitting area EA2, and the third light emitting area EA3, respectively.

The backplane substrate 110 may include a display area DA including light emitting areas EA. In one embodiment, the backplane substrate 110 may be a semiconductor circuit board formed through a semiconductor process using a silicon wafer. For example, a silicon wafer may be used as a base member to form the display panel 100.

The backplane substrate 110 may include pixel circuits PXC and pixel electrodes PXE, and interlayer insulating films INS1, INS2, and INS3 provided in the display area DA. For example, at least one light emitting element LE may be provided in each light emitting area EA of the display panel 100, and the backplane substrate 110 may include pixel circuits PXC and pixel electrodes PXE electrically connected to each of the light emitting elements LE disposed in the respective light emitting areas EA.

The pixel circuits PXC may be provided in the display area DA corresponding to the area where each pixel PX and/or the light emitting areas EA are formed. In one embodiment, each of the pixel circuits PXC may include a complementary metal-oxide semiconductor (CMOS) circuit formed using a semiconductor process.

Each of the pixel circuits PXC may include at least one transistor formed through a semiconductor process. Additionally, each of the pixel circuits PXC may further include at least one capacitor formed through a semiconductor process.

In one embodiment, a circuit insulation film INS1 may be disposed on the pixel circuits PXC. The circuit insulation film INS1 may be made of an inorganic film, such as a silicon nitride layer, a silicon oxynitride layer, a silicon oxide layer, a titanium oxide layer, or an aluminum oxide layer.

Pixel electrodes PXE may be disposed on the circuit insulation film INS1. The pixel electrodes PXE may be connected to the pixel circuits PXC through a contact hole penetrating the circuit insulation film INS1. Each of the pixel electrodes PXE may be electrically connected to the pixel circuits PXC. For example, the pixel electrodes PXE and the pixel circuits PXC may be connected in a one-to-one correspondence. Each of the pixel circuits PXC may apply a pixel voltage to the pixel electrode PXE connected thereto. Each of the pixel electrodes PXE may receive a pixel voltage from the pixel circuit PXC. The pixel electrodes PXE may include a conductive material (e.g., a metal material such as aluminum (Al)).

One or more interlayer insulating layers INS2 and INS3 may be disposed on the pixel electrodes PXE. In one embodiment, the interlayer insulating layers INS2 and INS3 may include a first interlayer insulating layer INS2 and a second interlayer insulating layer INS3.

The first interlayer insulating layer INS2 may be disposed on the pixel electrodes PXE, and the second interlayer insulating layer INS3 may be disposed on the first interlayer insulating layer INS2.

The first interlayer insulating layer INS2 and the second interlayer insulating layer INS3 may be formed of the same material but embodiments are not limited thereto. The first interlayer insulating layer INS2 and the second interlayer insulating layer INS3 may be formed of an inorganic film, such as a silicon nitride layer, a silicon oxynitride layer, a silicon oxide layer, a titanium oxide layer, or an aluminum oxide layer.

The backplane substrate 110 may further include the non-display area NDA shown in FIGS. 1 and 2. In one embodiment, the backplane substrate 110 may further include common electrode connecting portions CVS, first pads PD1, and/or second pads located in the non-display area NDA.

The light emitting element layer 120 may include a bottom bonding electrode BBE, an upper bonding electrode UBE, light emitting elements LE, element insulating layers INS4 and INS5, a reflective layer RF, and a common electrode CE. In one embodiment, the light emitting element layer 120 may further include an organic film ORL disposed around the light emitting elements LE and/or a third interlayer insulating layer INS6 disposed on the common electrode CE.

In one embodiment, the light emitting element layer 120 may further include additional components. For example, the light emitting element layer 120 may further include a reflective layer and/or a light blocking layer provided between the light emitting elements LE and/or on the sides of the light emitting elements LE.

The first interlayer insulating layer INS2 and the second interlayer insulating layer INS3 may have contact holes CH through them. Therefore, the pixel electrode PXE may be exposed by the contact hole CH.

Referring to FIG. 4, a through electrode TRE is disposed inside the contact hole CH. For example, the through electrode TRE may fill the contact hole CH and directly contact the pixel electrode PXE exposed by the contact hole CH.

The through electrode TRE may have an upper surface that is concave below the reference line (zero line), and in particular the center of the through electrode TRE may have a concave groove that is lower than the edge, for example, in a dish shape. The reference line may be an extension of the flattened surface of the second interlayer insulating layer INS3.

The through electrode TRE may include a conductive material. In one embodiment, the through electrode TRE may be made of a metal material such as copper (Cu) or the like.

Referring to FIG. 5, the bottom bonding electrode BBE may be disposed on the second interlayer insulating layer INS3 and the through electrode TRE. The bottom bonding electrode BBE may be connected to the pixel electrode PXE through the through electrode TRE.

The lower surface of the bottom bonding electrode BBE may follow the profile of the lower structure, and the upper surface of the bottom bonding electrode BBE may be formed to be flat. For example, the lower surface of the bottom bonding electrode BBE may have a protrusion that is concave downward corresponding to the concave shape of the through electrode TRE. Accordingly, the bottom bonding electrode BBE may be formed to fill the concave groove of the through electrode TRE.

In one embodiment, the bottom bonding electrode BBE may include a first bottom bonding electrode BBE1 and a second bottom bonding electrode BBE2 stacked on each other. The first bottom bonding electrode BBE1 may be disposed on the interlayer insulating layers INS2 and INS3, and the second bottom bonding electrode BBE2 may be disposed on the first bottom bonding electrode BBE1.

The lower surface of the first bottom bonding electrode BBE1 may have a downwardly concave protrusion corresponding to the concave shape of the through electrode TRE, and the upper surface BOE may be formed to be flat. On the other hand, both the upper and lower surfaces of the second bottom bonding electrode BBE may be formed to be flat.

The first bottom bonding electrode BBE1 may be composed of a single layer of a conductive material. For example, the first bottom bonding electrode BBE1 may include a barrier layer made of at least one of Ti, Ni, Pt, Sn, Au, Al, and W. In one embodiment, the first bottom bonding electrode BBE1 may be titanium (Ti). The first bottom bonding electrode BBE1 may include an oxide film. For example, the first bottom bonding electrode BBE1 may be formed of two layers and may include an oxide film at the interface between the layers.

The second bottom bonding electrode BBE2 may include at least one of Ti, Ni, Pt, Sn, Au, and Al. In one embodiment, the second bottom bonding electrode BBE2 may be gold (Au).

In one embodiment, the second bottom bonding electrode BBE2 may be formed of a different material from the first bottom bonding electrode BBE1 but is not limited thereto.

One or more layers of the upper bonding electrode UBE may be disposed on the bottom bonding electrode BBE.

The upper bonding electrode UBE may include a conductive bonding material suitable for bonding or adhering the light emitting elements LE to the bottom bonding electrode BBE.

The upper bonding electrode UBE may be a single-layer or multi-layer electrode containing Ti, Ni, Pt, Sn, Au, Al, or other metal materials (e.g., bonding metal).

In one embodiment, the upper bonding electrode UBE may include a first upper bonding electrode UBE1 and a second upper bonding electrode UBE2. The first upper bonding electrode UBE1 may directly contact the bottom bonding electrode BBE. The second upper bonding electrode UBE2 may be disposed on the first upper bonding electrode UBE1. The first upper bonding electrode UBE1 may include at least one of Ti, Ni, Pt, Sn, Au, and Al. In one embodiment, the first upper bonding electrode UBE1 may be gold (Au). The second upper bonding electrode UBE2 may include at least one of Ti, Ni, Pt, Sn, Au, Al, and W. In one embodiment, the second upper bonding electrode UBE2 may be titanium (Ti).

In one embodiment, the upper bonding electrode UBE is disclosed as a two-layer electrode layer but is not limited thereto. For example, the upper bonding electrode UBE may be formed as a single layer containing at least one of Ti, Ni, Pt, Sn, Au, and Al. In other embodiments, the upper bonding electrode UBE may include three electrode layers. For example, the upper bonding electrode UBE may include a first electrode layer made of Sn, a second electrode layer made of Au, and a third electrode layer made of Ti.

The light emitting element LE may be disposed on the upper bonding electrode UBE.

An end of the light emitting elements LE may be electrically connected to the pixel electrodes PXE through the upper bonding electrode UBE and the bottom bonding electrode BBE. Another end of the light emitting elements LE may be electrically connected to a common electrode.

The pixel electrodes PXE may be connected to each pixel circuit PXC. The pixel electrodes PXE may be individually provided in each light emitting area EA and may be electrically connected to the light emitting elements LE located in each light emitting area EA. Accordingly, the light emitting elements LE disposed in each light emitting area EA may be individually and/or independently controlled.

The light emitting elements LE may include semiconductor layers grown on a semiconductor substrate (e.g., a wafer substrate) by epitaxial growth. For example, the light emitting elements LE may include a first semiconductor layer doped with a first conductivity type, a second semiconductor layer doped with a second conductivity type, and an active layer between the first and second semiconductor layers.

The light emitting elements LE may be formed from an epitaxial thin film of wafer dies divided from an epitaxial wafer and may be patterned in a cell area corresponding to each display panel 100 to form respective emission areas EA. A detailed description of the structure and manufacturing method of the light emitting elements LE according to embodiments will be described later.

In one embodiment, a first element insulating layer INS4 may be disposed surrounding the light emitting element LE and the bonding electrodes BBE and UBE. The first element insulating layer INS4 may have an opening on the top surface of the light emitting element LE. Accordingly, at least a portion of the top surface of the light emitting element LE may be exposed through the opening of the first element insulating layer INS4. The first element insulating layer INS4 may be formed of an inorganic film, such as a silicon nitride layer, a silicon oxynitride layer, a silicon oxide layer, a titanium oxide layer, or an aluminum oxide layer.

A reflective layer RF may be further disposed on the side of the light emitting element LE and the bonding electrodes BBE and UBE on the first element insulating layer INS4. The reflective layer RF may serve to reflect light emitted from the light emitting element LE that travels in the upward, downward, left, right, or lateral direction rather than in the upward direction. The reflective layer RF may include a highly reflective metal material such as aluminum (Al).

A second element insulating layer INS5 may be provided on the reflective layer RF to surround the light emitting element LE and the bonding electrodes BBE and UBE. The second element insulating layer INS5 may have an opening on the top surface of the light emitting element LE. The opening of the second element insulating layer INS5 may overlap the opening of the first element insulating layer INS4. Accordingly, at least a portion of the top surface of the light emitting element LE may be exposed by the opening of the second element insulating layer INS5 and the opening of the first element insulating layer INS4. The second element insulating layer INS5 may be formed of an inorganic film, such as a silicon nitride layer, a silicon oxynitride layer, a silicon oxide layer, a titanium oxide layer, or an aluminum oxide layer.

An organic film ORL may be provided around the light emitting elements LE. As one example, the organic film ORL may be disposed between the light emitting areas EA to surround the light emitting areas EA provided with the light emitting elements LE and may surround the light emitting elements LE and the bonding electrodes BBE and UBE. In one embodiment, the organic film ORL may be a filler that fills the gap between the light emitting elements LE. The organic film ORL may expose a portion of the light emitting elements LE, for example, the upper surface.

The organic film ORL may include an insulating material. For example, the organic film ORL may be a single layer or multiple layers of organic insulating material including acrylic resin, epoxy resin, phenolic resin, polyamide resin, polyimide resin, or other organic insulating material.

The common electrode CE may be disposed on top of the light emitting elements LE that are not covered by the organic film ORL. In one embodiment, the common electrode CE may be entirely disposed in the display area DA to cover the light emitting elements LE and the organic film ORL. The common electrode CE may be a common layer commonly formed and/or connected to the light emitting elements LE of the display area DA and the pixels PX including the same.

The common electrode CE may be electrically connected to the common electrode connecting portions CVS disposed in the first common voltage supply area CVA1 and/or the second common voltage supply area CVA2 of FIGS. 1 and 2. Accordingly, the common electrode CE may be supplied with a common voltage through the common electrode connecting portions CVS.

The common electrode CE may include a transparent conductive material capable of transmitting light. For example, the common electrode CE may be made of indium tin oxide (ITO), indium zinc oxide (IZO), or other transparent conductive material. In one embodiment, it may function as a cathode electrode (or anode electrode) of the light emitting elements LE.

The third interlayer insulating layer INS6 may be disposed on the common electrode CE. For example, the third interlayer insulating layer INS6 may be a capping layer disposed entirely in the display area DA to cover the common electrode CE. The third interlayer insulating layer INS6 may include an inorganic insulating material such as silicon oxide (SiOₓ), silicon nitride (SiNₓ), silicon oxynitride (SiOₓN_{y}), aluminum oxide (AlₓO_{y}), aluminum nitride (AlN), or the like, or any other insulating material.

In one embodiment, the display panel 100 may include a lens-type optical structure LS provided on the light emitting element layer 120. Additionally, the display panel 100 may further include a protective layer PRL covering the lens-type optical structure LS.

The lens-type optical structure LS may be disposed in each light emitting area EA to overlap the light emitting elements LE. In one embodiment, the lens-type optical structure LS may be an optical structure in the form of a convex lens provided on top of the light emitting elements LE, but the type and/or shape of the optical structure is not limited thereto. By disposing the lens-type optical structure LS on top of the light emitting elements LE, the light output characteristics of the pixels PX may be adjusted and/or improved.

The lens-type optical structure LS may be formed of a transparent material to allow light incident from the light emitting elements LE to be transmitted. For example, the lens-type optical structure LS may be formed of glass, plastic, ceramic, or other materials, and may be formed of an optical material with a high refractive index.

The protective layer PRL may be disposed on the lens-type optical structure LS to cover the lens-type optical structure LS. The protective layer PRL may be formed of a transparent and durable material (e.g., plastic or organic glass, optical glass, ceramic, etc.), but is not particularly limited thereto, as long as the material is suitable for protecting the lens-type optical structure LS. Although FIG. 3 illustrates an embodiment in which the protective layer PRL has a curve corresponding to the shape of the lens-type optical structure LS, the embodiments are not limited thereto. For example, the protective layer PRL may be formed in a shape that may planarize the top surface of the display panel 100 on which the lens-type optical structure LS is formed.

FIG. 6 is an enlarged schematic cross-sectional view illustrating another example of the insulating layer and through electrode of FIG. 4.

Referring to FIG. 6, it may be different from the example shown with reference to FIG. 4 at least in that a barrier film BR surrounding the through electrode TRE may be further disposed on the inner surface of the contact hole CH. Referring to FIG. 6, the barrier film BR may include a material such as SiN to prevent the movement of metal ions forming the through electrode TRE.

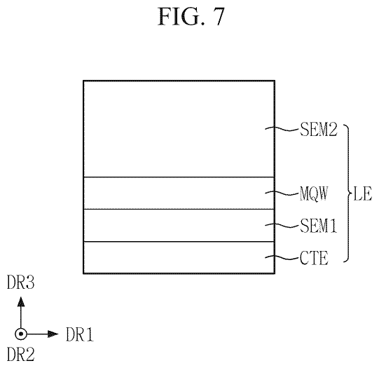

FIG. 7 is a schematic cross-sectional view illustrating a light emitting element according to one embodiment.

Referring to FIG. 7, the light emitting element LE may include a first semiconductor layer SEM1, an active layer MQW, and a second semiconductor layer SEM2 sequentially arranged and/or stacked along the third direction DR3. In one embodiment, the light emitting element LE may further include a contact electrode CTE provided at an end. For example, the light emitting element LE may further include a contact electrode CTE provided at an end where the first semiconductor layer SEM1 is located.

The light emitting element LE may further include additional layers depending on embodiments. For example, the light emitting element LE may further include an electron blocking layer disposed between the first semiconductor layer SEM1 and the active layer MQW, and/or a superlattice layer disposed between the active layer MQW and the second semiconductor layer SEM2.

In one embodiment, the light emitting element LE may be an inorganic light emitting element made of an inorganic material. For example, the light emitting element LE may be an inorganic light emitting diode formed from a nitride-based semiconductor material such as GaN, AlGaN, InGaN, AlInGaN, AlN or InN, a phosphide-based semiconductor material such as GaP, GaInP, AlGaP, AlGaInP, AIP or InP, or any other inorganic material.

The contact electrode CTE may be provided and/or formed at an end of the light emitting element LE where the first semiconductor layer SEM1 is disposed. For example, the contact electrode CTE may be provided and/or formed on a surface of the first semiconductor layer SEM1. The contact electrode CTE may be an electrode that protects the first semiconductor layer SEM1 and smoothly connects the first semiconductor layer SEM1 to at least one circuit element, electrode, wiring, and/or conductive layer. The contact electrode CTE may include a metal, metal oxide, or other conductive material.

The first semiconductor layer SEM1 may be disposed on the contact electrode CTE. In one embodiment, the first semiconductor layer SEM1 may include a nitride-based semiconductor material or a phosphide-based semiconductor material. For example, the first semiconductor layer SEM1 may include a nitride-based semiconductor material including at least one of GaN, AlGaN, InGaN, AlInGaN, AlN, and InN, or a phosphide-based semiconductor material including at least one of GaP, GaInP, AlGaP, AlGaInP, AIP, and InP. The first semiconductor layer SEM1 may include other materials.

The first semiconductor layer SEM1 may include a semiconductor material doped with a first conductivity type dopant. For example, the first semiconductor layer SEM1 may include GaN (e.g., p-type dopant) doped with a first conductive dopant (e.g., p-type dopant) such as Mg, Zn, Ca, Se, Ba, or the like.

The active layer MQW may be disposed on the first semiconductor layer SEM1. The active layer MQW may emit light by recombination of electron-hole pairs according to an electrical signal applied through the first semiconductor layer SEM1 and the second semiconductor layer SEM2. For example, the active layer MQW may be a light emitting layer of the light emitting element LE.

The active layer MQW may include a material with a single or multiple quantum well structure. In case that the active layer MQW includes a material with a multi-quantum well structure, the active layer MQW may have a structure in which well layers and barrier layers are alternately stacked. The active layer MQW may include three to five different semiconductor materials, depending on the wavelength band of the light emitted.

In one embodiment, the active layer MQW may include a nitride-based semiconductor material or a phosphide-based semiconductor material. For example, the active layer MQW may include a nitride-based semiconductor material including at least one of GaN, AlGaN, InGaN, InGaAlN, AlN, InN, and AlInN, or a phosphide-based semiconductor material including at least one of GaP, GaInP, AlGaP, AlGaInP, AlP, and InP. For example, the well layer may be formed of InGaN, and the barrier layer may be formed of GaN or AlGaN, but embodiments are not limited thereto. In case that the active layer MQW includes InGaN, the color of light emitted from the light emitting element LE may be controlled by adjusting the content of indium (In). The active layer MQW may also include other materials.

In one embodiment, the active layers MQW of the first light emitting element LE1, the second light emitting element LE2, and the third light emitting element LE3 shown in FIGS. 2 and 3 may emit light of the same color (e.g., blue light) as each other. In another embodiment, the active layers MQW of the first light emitting element LE1, the second light emitting element LE2, and the third light emitting element LE3 may emit different colors of light (e.g., red light, green light, and blue light, respectively).

The second semiconductor layer SEM2 may be disposed on the active layer MQW. In one embodiment, the second semiconductor layer SEM2 may include a nitride-based semiconductor material or a phosphide-based semiconductor material. For example, the second semiconductor layer SEM2 may include a nitride-based semiconductor material including at least one of GaN, AlGaN, InGaN, AlInGaN, AlN, and InN, or a phosphide-based semiconductor material including at least one of GaP, GaInP, AlGaP, AlGaInP, AIP, and InP. The second semiconductor layer SEM2 may also include other materials.

The second semiconductor layer SEM2 may include a semiconductor material doped with a second conductivity type dopant. For example, the second semiconductor layer SEM2 may include GaN (e.g., n-GaN) doped with a second conductive dopant (e.g., n-type dopant), such as Si, Ge, Sn, or the like.

In one embodiment, the first semiconductor layer SEM1 and the second semiconductor layer SEM2 may have different thicknesses in a thickness direction of the light emitting element LE (e.g., the third direction DR3). For example, the second semiconductor layer SEM2 may have a larger thickness than the first semiconductor layer SEM1 in the thickness direction of the light emitting element LE. Accordingly, the active layer MQW may be located closer to a first end (for example, a p-type end) of the light emitting element LE provided with the first semiconductor layer SEM1 than to a second end (for example, an n-type end) of the light emitting element LE provided with the second semiconductor layer SEM2.

In one embodiment, the light emitting element LE may be a vertical micro-LED extending and/or stacked in the third direction DR3. For example, the light emitting element LE may be a micro-LED having a length in the first direction DR1, a length in the second direction DR2, and a length in the third direction DR3 of tens to hundreds of micrometers (μm), respectively. In one embodiment, the length of the light emitting element LE in the first direction DR1, the length in the second direction DR2, and the length in the third direction DR3 may each be approximately 100 μm or less.

In one embodiment, the light emitting element LE may include a substantially vertical side surface as shown in FIG. 7. For example, the light emitting element LE may be patterned through vertical etching and may have a rectangular or square cross-sectional shape where the width of the top surface and the width of the lower surface are substantially equal.

The shape of the light emitting element LE may be varied in different embodiments. For example, the light emitting element LE may have a cross-sectional shape in which the width of the top surface and the width of the lower surface are different.

In one embodiment, the light emitting element LE may have an inverted tapered cross-sectional shape. For example, the light emitting element LE may have an inverted trapezoidal cross-sectional shape in which the width of the top surface is wider than the width of the lower surface.

In one embodiment, the light emitting element LE may be disposed on the backplane substrate 110 such that the first semiconductor layer SEM1 is located below the active layer MQW and the second semiconductor layer SEM2 is located above the active layer MQW, as shown in FIG. 7. For example, the light emitting element LE may be disposed in each light emitting area EA such that the contact electrode CTE (or first semiconductor layer SEM1) is in contact with the upper bonding electrode UBE in FIG. 3 and the second semiconductor layer SEM2 (or other contact electrode provided on the second semiconductor layer SEM2) is in contact with the common electrode CE. In this case, the common electrode CE may be a cathode electrode.

The structure, material, size, and/or shape of the light emitting element LE are not limited to the above-described embodiments. For example, the structure, material, size, and/or shape of the light emitting element LE may be varied in different embodiments.

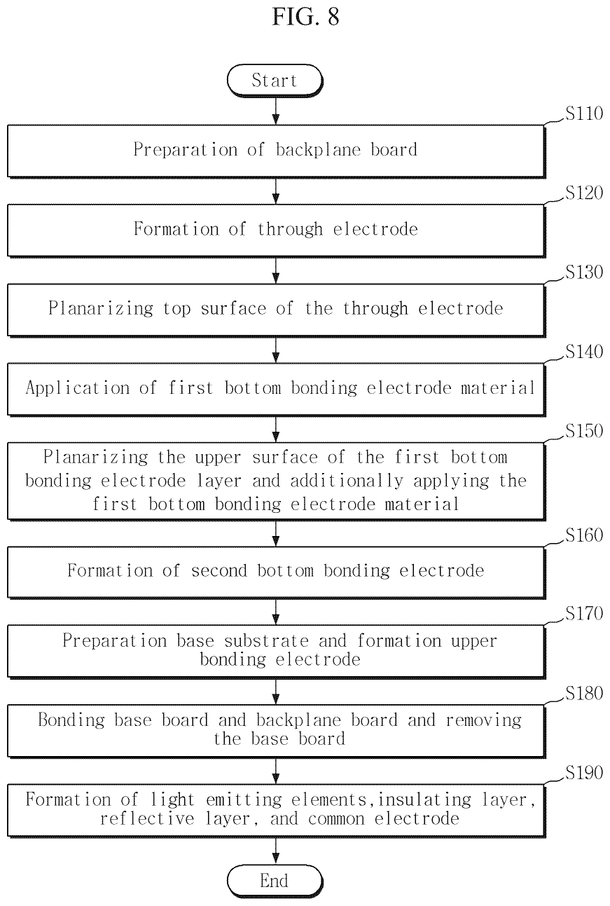

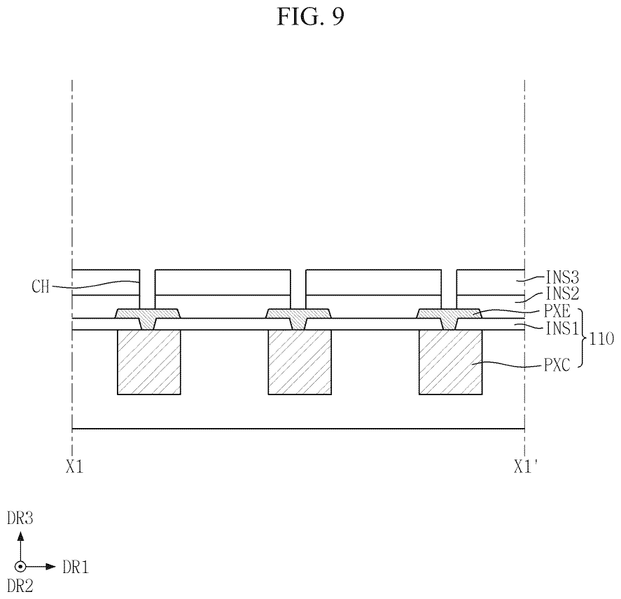

FIG. 8 is a flowchart illustrating a manufacturing method of a display device according to one embodiment. For example, FIG. 8 is a flowchart illustrating a method of manufacturing the display panel 100 of the display device 10 according to one embodiment. FIGS. 9 to 25 are schematic diagrams to illustrate a method of manufacturing a display panel according to one embodiment. For example, FIGS. 9 to 25 each illustrate specific steps for forming the display panel 100 in the form of a perspective view, cross-sectional view, or plan view.

Referring to FIG. 9, a backplane substrate 110 including a contact hole CH exposing at least a portion of the pixel electrode PXE may be provided in the interlayer insulating layers INS2 and INS3 (S110 in FIG. 8). FIG. 9 is a cross-sectional view illustrating a schematic shape of the backplane substrate 110.

The backplane substrate 110 may include pixel electrodes PXE and interlayer insulating layers INS2 and INS3. For example, the backplane substrate 110 may include pixel electrodes PXE spaced apart from each other, and interlayer insulating layers INS2 and INS3 covering the pixel electrodes PXE. The interlayer insulating layers INS2 and INS3 may have a contact hole CH that penetrates the interlayer insulating layers INS2 and INS3 on each of the pixel electrodes PXE and exposes at least a portion of the pixel electrode PXE.

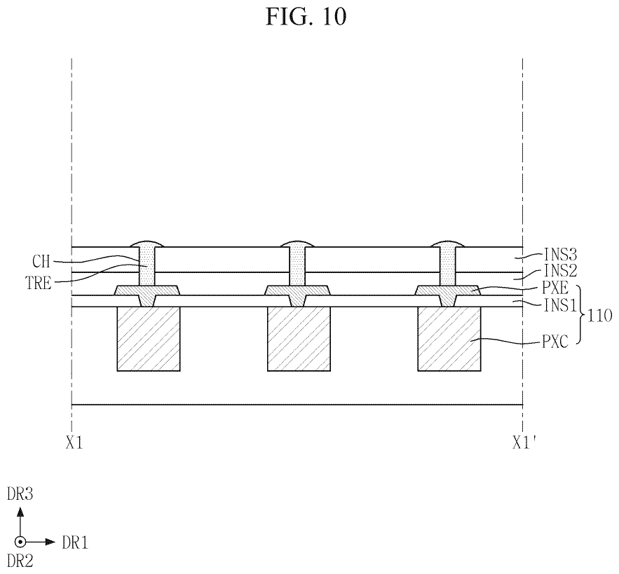

Referring to FIG. 10, a through electrode TRE may be formed in the contact hole CH. (S120 in FIG. 8)

The contact hole CH may be formed by an etching method such as laser or ion etching.

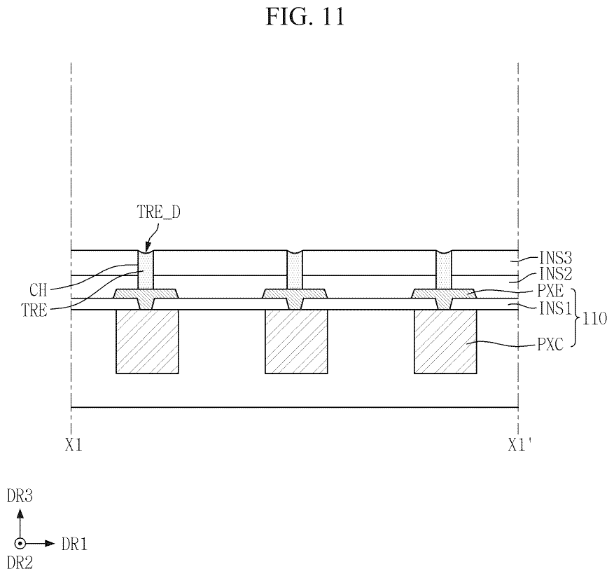

Referring to FIG. 11, the top surface of the through electrode TRE may be planarized (S130 of FIG. 8). In one embodiment, the planarization process may be performed by a polishing process such as a chemical mechanical polishing (CMP) process.

In the chemical mechanical polishing (CMP) process, a slurry composition containing an abrasive may be used to planarize the through electrode protruding onto the interlayer insulating layers INS2 and INS3 by contacting the through electrode TRE with an abrasive pad and moving the abrasive pad in an orbital motion that is a combination of rotational and linear motion.

The slurry composition used in the CMP process may be largely composed of compounds such as abrasive particles that act physically and etchants that act chemically. Therefore, the slurry composition may perform a more optimized and extensive planarization process by selectively etching the exposed portion of the wafer surface through physical and chemical actions. In one embodiment, the slurry composition is for planarization the through electrode TRE that protrudes outward from the interlayer insulating layers INS2 and INS3 and includes a material that causes the through electrode TRE to soften faster than the interlayer insulating layers INS2 and INS3. Therefore, in case of polishing the surface where the interlayer insulating layers INS2 and INS3 and the through electrode TRE are exposed to the outside by the slurry composition, dishing TRE_D may occur on the through electrode TRE formed with the material with a faster polishing rate.

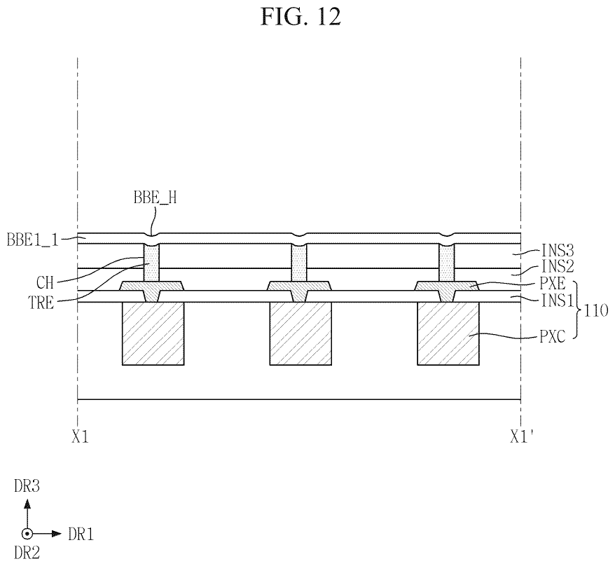

Referring to FIG. 12, a first bottom bonding electrode material may be applied. (S140 in FIG. 8)

For example, a conductive first bottom bonding electrode layer BBE1_1 may be formed by entirely applying a conductive bonding material on the top surfaces of the through electrode TRE and the interlayer insulating layer INS2 and INS3 where dishing TRE_D occurred.

The first bottom bonding electrode layer BBE1_1 may follow the surface profile of the lower structure (the second interlayer insulating layer INS3 and through electrode TRE). Accordingly, the first bottom bonding electrode layer BBE1_1 may include a groove BBE_H corresponding to a location where dishing of the through electrode TRE occurs on both the lower and upper surfaces.

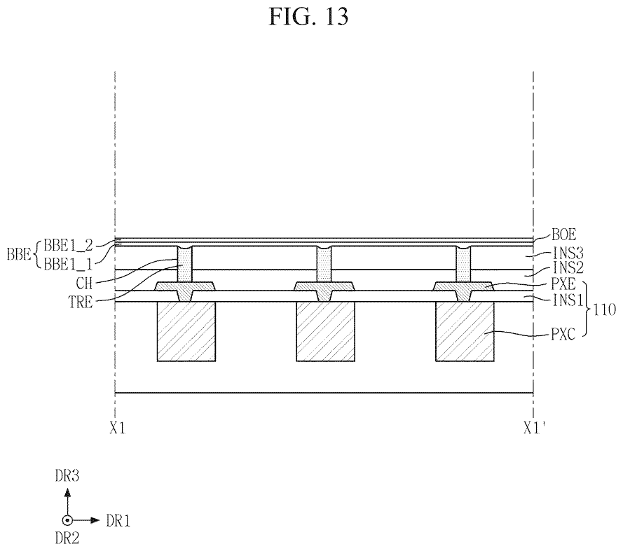

Referring to FIG. 13, the first bottom bonding electrode layer BBE1_1 may be planarized and a first bottom bonding electrode material may be further applied. (S150 in FIG. 8)

In one embodiment, the planarization process may be performed by a polishing process such as a chemical mechanical polishing (CMP) process. Through the planarization process, the upper surface of the first bottom bonding electrode layer BBE1_1 may be planarized so that the groove BBE_H on the top surface may be removed. Further, an oxide layer may be formed on the upper surface of the first bottom bonding electrode layer BBE1_1 through the planarization process.

A conductive bonding material may be applied entirely on the upper surface of the first bottom bonding electrode layer BBE1_1 on which the oxide layer is formed. As a result, the conductive first bottom bonding electrode BBE1 may be formed.

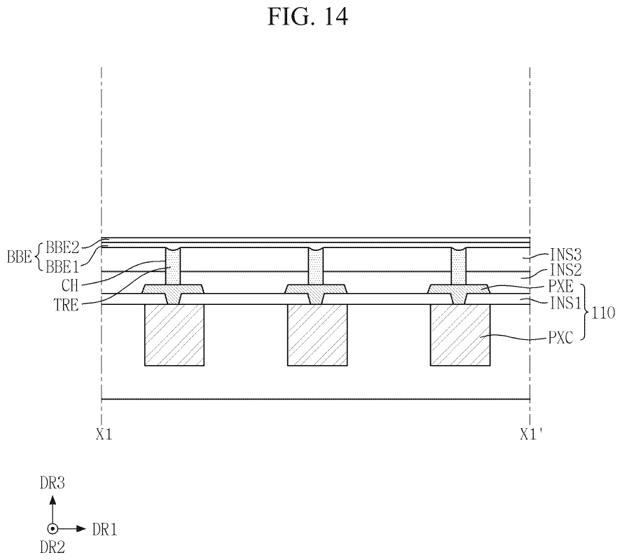

Referring to FIG. 14, a second bottom bonding electrode BBE2 may be formed on the first bottom bonding electrode BBE1. (S160 in FIG. 8)

For example, the conductive second bottom bonding electrode BBE2 may be formed by entirely applying a conductive bonding material on the upper surface of the first bottom bonding electrode BBE1. The conductive material used to form the second bottom bonding electrode BBE2 may be different from the conductive material used to form the first bottom bonding electrode BBE1. For example, the first bottom bonding electrode BBE1 may be made of titanium (Ti), and the second bottom bonding electrode BBE2 may be made of gold (Au) but embodiments are not limited thereto.

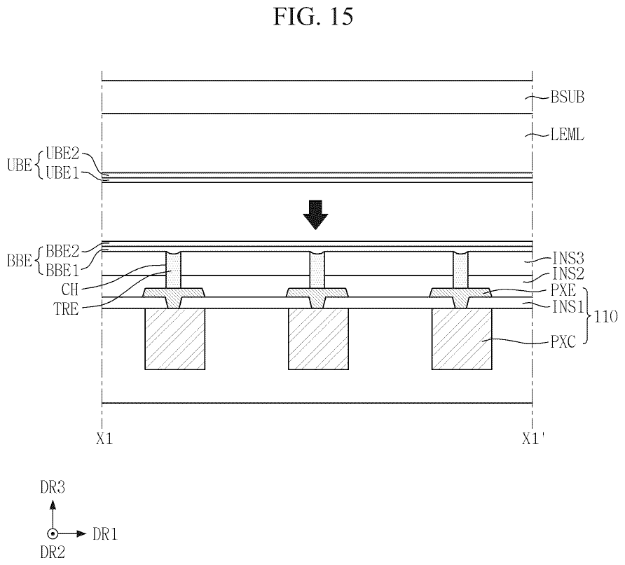

Referring to FIG. 15, a base substrate BSUB on which semiconductor material layers LEML are stacked is prepared, and an upper bonding electrode UBE is formed. (S170 in FIG. 8)

The base substrate BSUB may be a semiconductor substrate suitable for epitaxial growth of a semiconductor. For example, the base substrate BSUB may be a substrate containing a material such as silicon (Si), sapphire, SiC, GaN, GaAs, or ZnO. If epitaxial growth for manufacturing the light emitting element LE may be performed smoothly, the type, material, and shape of the base substrate BSUB are not particularly limited.

The semiconductor material layers LEML may include a third semiconductor layer, a second semiconductor layer SEM2, an active layer MQW, and a first semiconductor layer SEM1 sequentially disposed on the base substrate BSUB.

For example, as shown in FIG. 7, on the base substrate BSUB, the third semiconductor layer, the second semiconductor layer SEM2, the active layer MQW, and the first semiconductor layer SEM1 may be formed sequentially through epitaxial growth. In one embodiment, the third semiconductor layer, the second semiconductor layer SEM2, the active layer MQW, and the first semiconductor layer SEM1 may be formed by epitaxial growth utilizing a process technology such as metal-organic chemical vapor deposition (MOCVD), metal-organic vapor phase epitaxy (MOVPE), molecular beam epitaxy (MBE), liquid phase epitaxy (LPE), or vapor phase epitaxy (VPE).

The third semiconductor layer may be disposed to reduce the difference in lattice constant between the second semiconductor layer SEM2 and the base substrate BSUB. As one example, the third semiconductor layer may include an undoped semiconductor and may be a material that is not doped as n-type or p-type. In one embodiment, the third semiconductor layer may be at least one of undoped InAlGaN, GaN, AlGaN, InGaN, AlN, and InN but is not limited thereto.

The second semiconductor layer SEM2 may be formed of the material of the previous example second semiconductor layer SEM2. For example, the second semiconductor layer SEM2 may be formed of at least one nitride-based semiconductor material or phosphide-based semiconductor material and may be formed as a single-layer or multi-layer semiconductor layer. The second semiconductor layer SEM2 may be doped to include a second conductivity type dopant (e.g., an n-type dopant).

The active layer MQW may be formed of the material of the previous example active layer MQW. For example, the active layer MQW may be formed of at least one nitride-based semiconductor material or phosphide-based semiconductor material. In one embodiment, a barrier layer and a quantum well layer may be alternately and/or repeatedly formed on the second semiconductor layer SEM2 to form an active layer MQW having a multi-quantum well structure.

The first semiconductor layer SEM1 may be formed of the material of the previous example first semiconductor layer SEM1. For example, the first semiconductor layer SEM1 may be formed of a single nitride-based semiconductor material or a phosphide-based semiconductor material or may be formed as a single layer or multiple layers of semiconductor layers. The first semiconductor layer SEM1 may be doped to include a first conductivity type dopant (e.g., a p-type dopant).

In one embodiment, in case of manufacturing a light emitting element LE including a contact electrode CTE as in the embodiments of FIG. 7, a process for forming a contact electrode CTE (or a conductive layer for forming a contact electrode CTE) on the semiconductor material layer LEML may be further performed. For example, it may further include a contact electrode CTE formed on the first semiconductor layer SEM1.

The contact electrode CTE may be formed of the material of the contact electrode CTE previously described. The contact electrode CTE may be formed through a process such as applying (e.g., depositing) a conductive material on the semiconductor material layer LEML, and the method of forming the contact electrode CTE is not particularly limited.

One or more layers of upper bonding electrode material may be formed on the top surface of the semiconductor material layer LEML (or contact electrode CTE). (S170 in FIG. 8)

For example, the second upper bonding electrode UBE2 may be formed by entirely applying a second bonding electrode material to the top surface of the first semiconductor layer SEM1. Thereafter, the first upper bonding electrode UBE1 may be formed by entirely applying the first bonding electrode material on the second upper bonding electrode UBE2. In one embodiment, the second bottom bonding electrode BBE2 may be made of titanium (Ti), and the first bottom bonding electrode BBE1 may be made of gold (Au) but embodiments are not limited thereto.

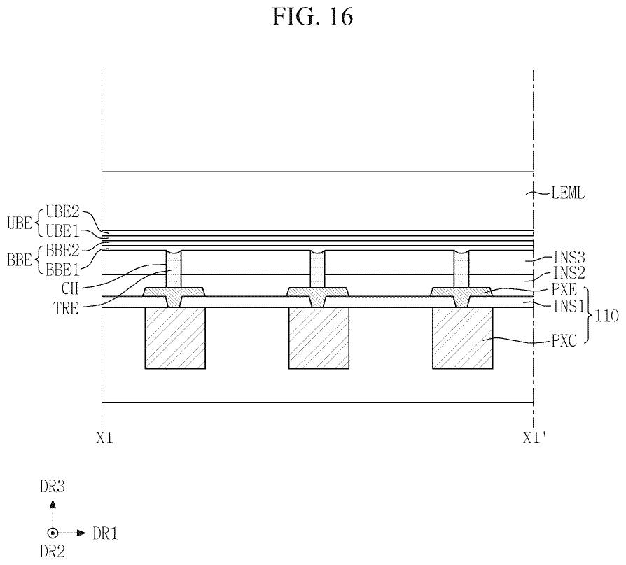

Referring to FIGS. 15 and 16, the base substrate BSUB and the backplane substrate 110 may be bonded and the base substrate BSUB may be removed (S180 in FIG. 8).

For example, referring to FIGS. 15 and 16, the upper bonding electrode UBE of the base substrate BSUB may be positioned to face the bottom bonding electrode BBE of the backplane substrate 110. Thereafter, the base substrate BSUB may be placed on the backplane substrate 110 for bonding such that the upper bonding electrode UBE and the bottom bonding electrode BBE are in contact with each other. Accordingly, semiconductor layers of the backplane substrate 110 may be bonded to the backplane substrate 110.

In one embodiment, the bottom bonding electrode BBE of the backplane substrate 110 and the upper bonding electrode UBE of the base substrate BSUB may be bonded by a bonding process of the base substrate BSUB to the backplane substrate 110 by a thermal compression (TC) bonding method. The method of bonding (or adhering) the base substrate BSUB to the backplane substrate 110 is not limited to this, and the backplane substrate 110 and the base substrate BSUB may be bonded in other ways.

The base substrate BSUB may be removed.

For example, a laser beam may be irradiated to the base substrate BSUB using a laser device to separate the semiconductor material layers LEML from the base substrate BSUB. The base substrate BSUB may be separated from the third semiconductor layer of the semiconductor material layers LEML.

The process of separating the base substrate BSUB may be separated by a laser lift off (LLO) process. The laser lift-off process utilizes a laser, and a KrF excimer laser (about 248 nm wavelength) may be used as the source but embodiments are not limited to this. By irradiating a laser to the base substrate BSUB, the base substrate BSUB may be separated from the semiconductor material layers LEML.

In some cases, the third semiconductor layer may be removed, for example by gluing.

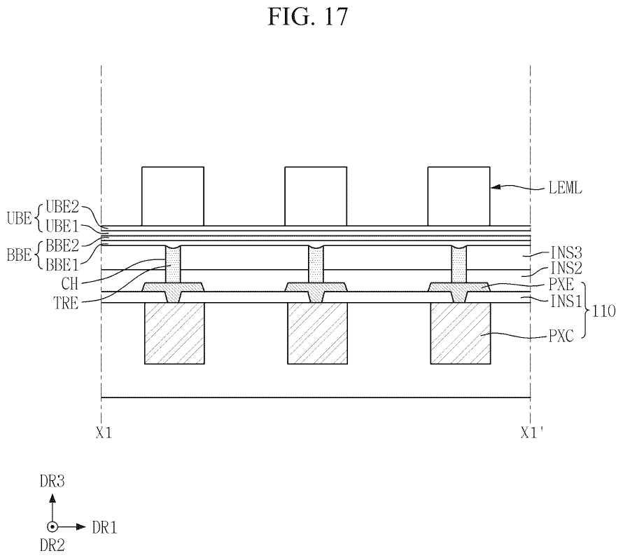

Referring to FIGS. 17 to 25, the light emitting element LE may be etched, and a subsequent process including a process for forming element insulating layers INS4 and INS5, a reflective layer RF, and a common electrode CE may be performed (S190 in FIG. 8).

For example, referring to FIG. 17, semiconductor material layers LEML may be etched using a mask to form light emitting elements LE.

Additional layers of semiconductor material may be etched by appropriate methods. For example, the process for etching the semiconductor material layers may be dry etching, wet etching, reactive ion etching (RIE), deep reactive ion etching (DRIE), inductively coupled plasma reactive ion etching (ICP-RIE), or the like. In the case of a dry etching method, anisotropic etching may be possible and may be suitable for vertical etching. In case of utilizing the etching method described above, the etching etchant may be Cl₂ or O₂. However, embodiments are not limited to this.

For example, the semiconductor material layer that overlaps the mask may not be etched, and the semiconductor material layer that does not overlap the mask may be etched to form the light emitting elements LE. Accordingly, the light emitting elements LE may be formed including a third semiconductor layer, a second semiconductor layer SEM2, a superlattice layer SLT, an active layer MQW, an electron barrier layer EBL, and a first semiconductor layer SEM1.

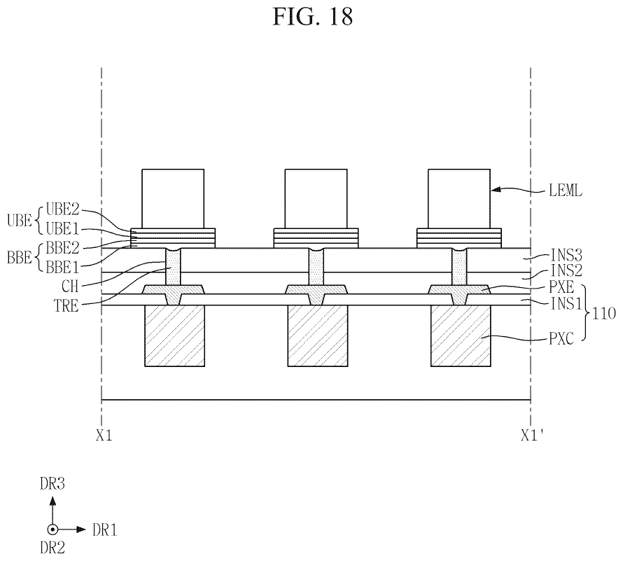

Referring to FIG. 18, the upper bonding electrode UBE and the bottom bonding electrode BBE may be etched.

For example, the upper bonding electrode UBE and the bottom bonding electrode BBE may be etched using the etched light emitting element LE as a mask. Accordingly, the upper bonding electrode UBE and the bottom bonding electrode BBE may protrude outward from the light emitting element LE but embodiments are not limited to this. The process of etching the upper bonding electrode UBE and the bottom bonding electrode BBE may be similar to the process of etching the semiconductor material layers.

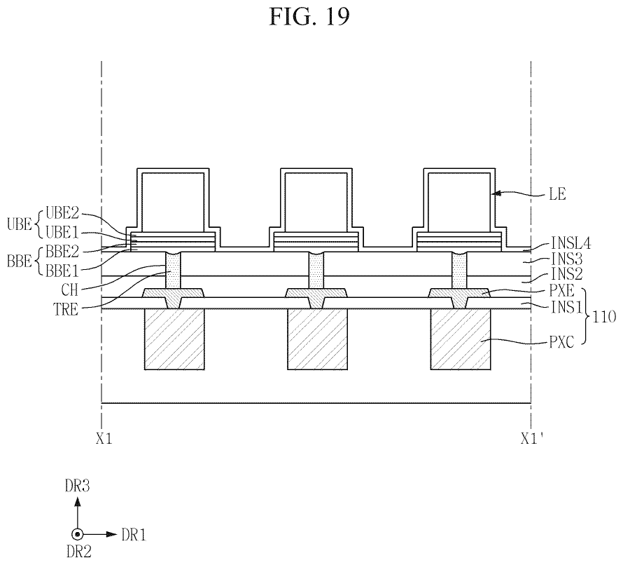

Referring to FIG. 19, an insulating material may be applied entirely to the backplane substrate 110 on which the light emitting element LE is formed, thereby forming a first element insulating layer INS4.

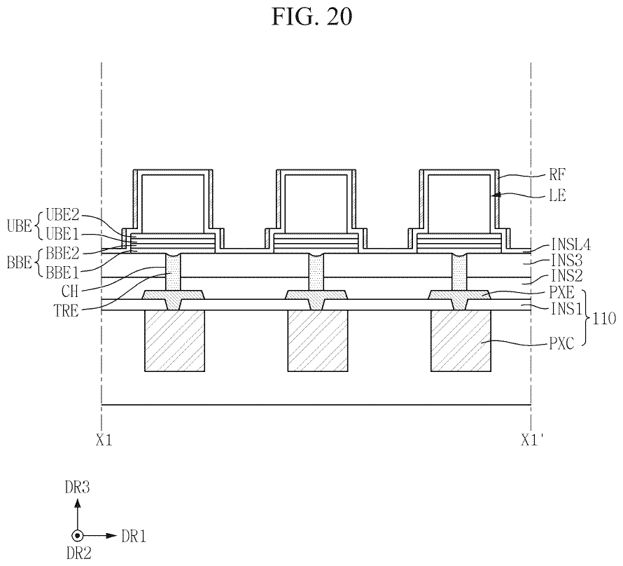

Referring to FIG. 20, a reflective layer RF may be formed on the first element insulating layer INS4 surrounding the side of the light emitting element LE and the side of the bonding electrodes UBE and BBE.

For example, a reflective material may be deposited to cover the first element insulating layer INS4. A large voltage difference may be formed in the third direction DR3 without a separate mask, and the reflective layer may be etched using an etching material. In this case, the etching material moves in the third direction DR3 i.e., from the top to the bottom, and the reflective layer RF may be etched. As a result, as shown in FIG. 20, the reflective layer RF disposed on the horizontal plane defined by the first direction DR1 and the second direction DR2 may be removed, whereas the reflective layer RF disposed on the vertical plane defined by the third direction DR3 may not be removed, as shown in FIG. 20. Therefore, the reflective layer RF disposed on the top surface of the fourth insulating layer INS4 may be removed. The reflective layer RF disposed on the side of the light emitting element LE and the side of the bonding electrodes UBE and BBE may not be removed.

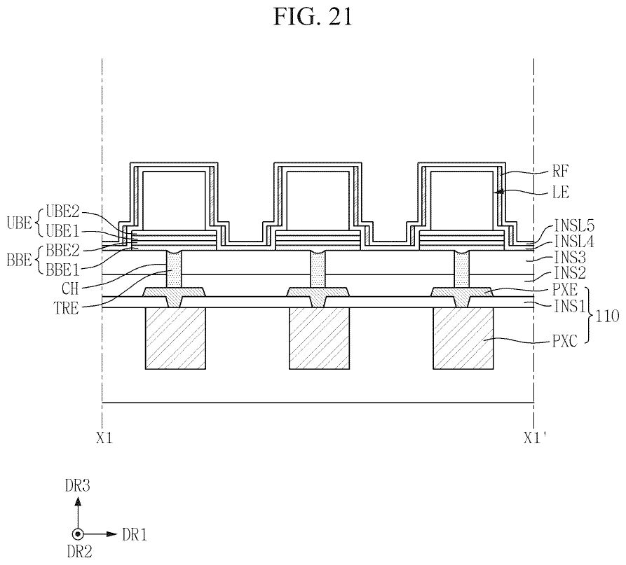

Referring to FIG. 21, a second element insulating layer INS5 may be formed by entirely applying an insulating material on the first element insulating layer INS4 and the reflective layer RF.

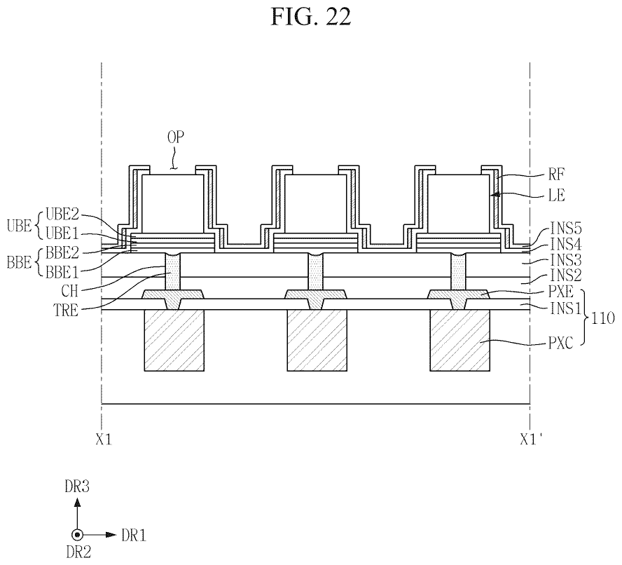

Referring to FIG. 22, an opening OP may be formed in the first element insulating layer INS4 and the second element insulating layer INS5 on the light emitting element LE to expose the top surface of the light emitting element LE.

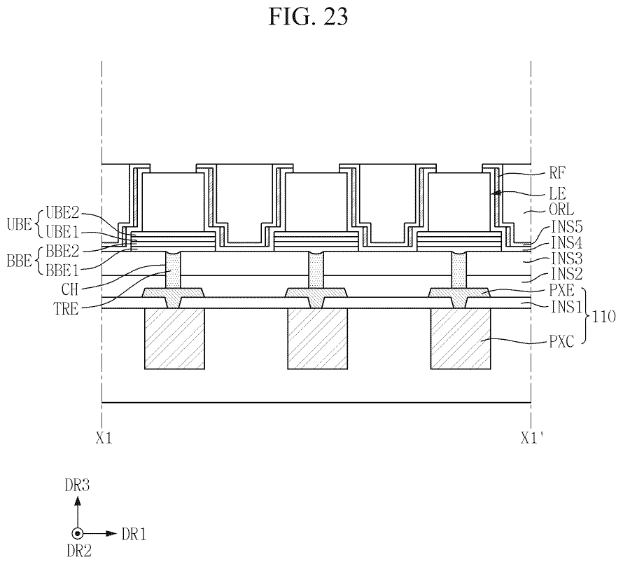

Referring to FIG. 23, an organic layer ORL may be formed between the light emitting elements LE.

For example, a filler may be applied between the light emitting elements LE to fill the organic layer ORL between the light emitting elements LE.

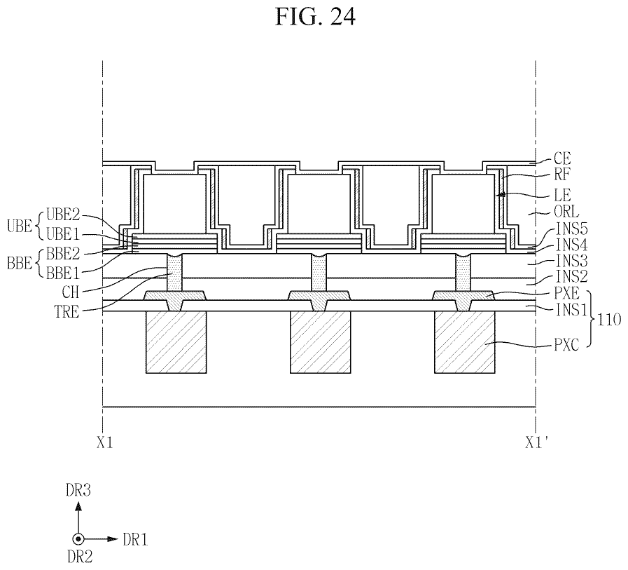

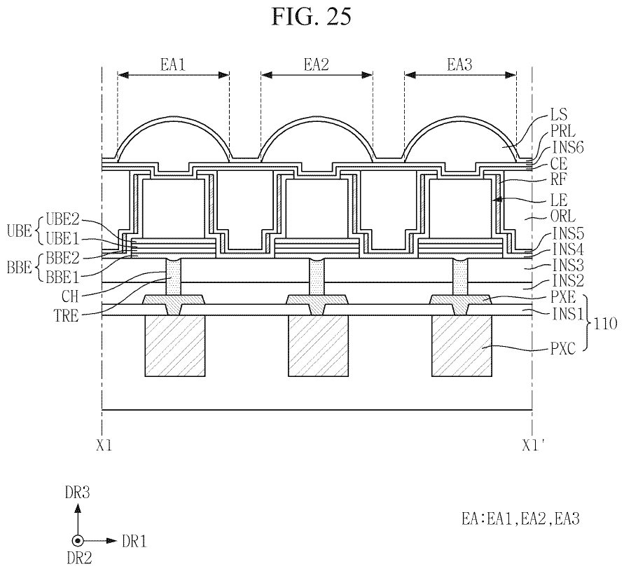

Referring to FIGS. 24 and 25, subsequent processes to form the light emitting element layer 120 may be performed, including a process to form a common electrode CE.

In one embodiment, in case of manufacturing the display panel 100 including a light conversion layer and/or a color filter layer, a process for forming the light conversion layer and/or the color filter layer on top of the light emitting element layer 120 or inside the light emitting element layer 120 may be further performed.

In one embodiment, in case of manufacturing the display panel 100 including the lens-type optical structure LS as shown in FIG. 3, the process may further include attaching and/or forming the lens-type optical structure LS and the protective layer PRL on the light emitting element layer 120.

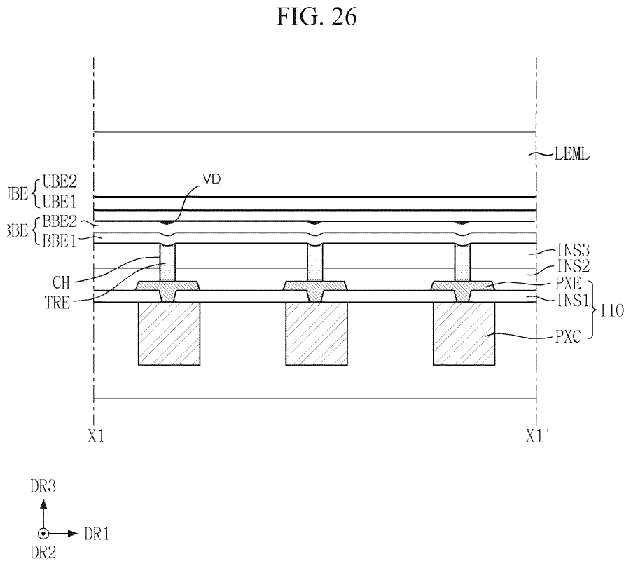

FIG. 26 is a cross-sectional view to illustrate a void VD that may occur in case that a planarization process is not performed on the bottom bonding electrode. FIG. 26 is a schematic cross-sectional view of a comparative embodiment of a method described with reference to FIGS. 12 to 16.

As shown in FIG. 11, after the interlayer insulating layers INS2 and INS3 having different etch rates and the top surface of the through electrode TRE may be planarized to form a dishing on the top surface of the through electrode TRE, the first bottom bonding electrode BBE1 and the second bottom bonding electrode BBE2 may be formed sequentially on the interlayer insulating layers INS2 and INS3 and the through electrode TRE, as shown in FIG. 12. The first bottom bonding electrode BBE1 and the second bottom bonding electrode BBE2 may have grooves (concavo-convex) corresponding to the grooves on the top surface of the through electrode TRE.

A base substrate BSUB including the upper bonding electrode layer UBE and semiconductor layers LEML may be bonded to the bottom bonding electrode BBE. Accordingly, a void may occur between the bottom bonding electrode BBE and the upper bonding electrode UBE corresponding to the groove (concavo-convex) points of the first bottom bonding electrode BBE1 and the second bottom bonding electrode (BBE2), resulting in an unbonded spot. If an unbonded spot occurs between the bottom bonding electrode BBE and the upper bonding electrode UBE, the electrical resistance in the vertical direction may increase and the risk of disconnection between the light emitting element LE and the pixel circuit PXC occurs. Such disconnection may be a greater risk in display devices with higher resolution.

On the other hand, according to one embodiment, since full polishing may be performed on the upper surface of the bottom bonding electrode BBE, even if unevenness is formed on the lower surface of the bottom bonding electrode BBE, the upper surface may be formed to be flat, thereby preventing or minimizing the generation of voids between the bottom bonding electrode BBE and the upper bonding electrode UBE. Accordingly, the risk of disconnection between the light emitting element LE and the pixel circuit PXC may be minimized.

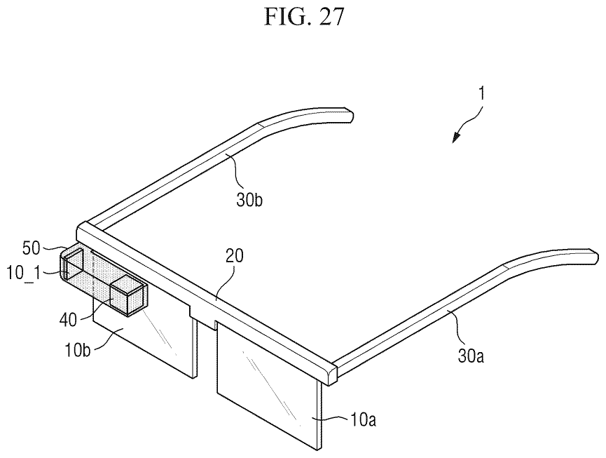

FIG. 27 is a schematic diagram illustrating a virtual reality device including a display device according to an embodiment. FIG. 27 illustrates a virtual reality device 1 in which the display device 10 according to an embodiment may be provided.

Referring to FIG. 27, the virtual reality device 1 according to an embodiment may be a device in a form of glasses. The virtual reality device 1 according to an embodiment may include a display device 10, a left-eye lens 10a, a right-eye lens 10b, a support frame 20, left and right legs 30a and 30b, a reflective member 40, and a display device housing 50.

FIG. 27 illustrates the virtual reality device 1 including the two legs 30a and 30b. However, the disclosure is not limited thereto. The virtual reality device 1 according to an embodiment may be used in a head-mounted display including a head-mounted band that may be mounted on a head instead of the legs 30a and 30b. For example, the virtual reality device 1 according to an embodiment may not be limited to the example shown in FIG. 27, and may be applied in various forms and in various electronic devices.

The display device housing 50 may receive the display device 10 and the reflective member 40. An image displayed on the display device 10 may be reflected from the reflective member 40 and provided to a user's right eye through the right-eye lens 10b. Thus, the user may view a virtual reality image displayed on the display device 10 via the right eye.

FIG. 27 illustrates that the display device housing 50 is disposed at a right end of the support frame 20. However, embodiments of the disclosure are not limited thereto. For example, the display device housing 50 may be disposed at a left end of the support frame 20. In this case, the image displayed on the display device 10 may be reflected from the reflective member 40 and provided to the user's left eye via the left-eye lens 10a. Thus, the user may view the virtual reality image displayed on the display device 10 via the left eye. As another example, the display device housing 50 may be disposed at each of the left end and the right end of the support frame 20. In this case, the user may view the virtual reality image displayed on the display device 10 via both the left eye and the right eye.

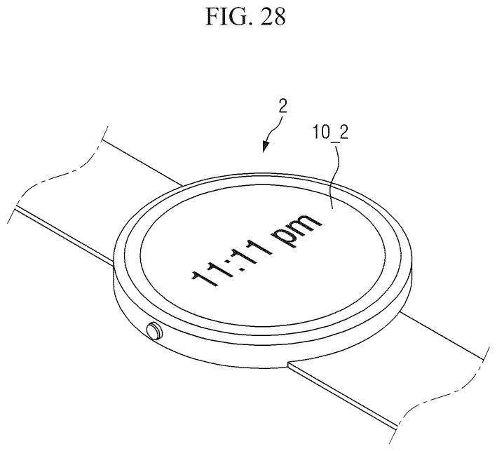

FIG. 28 is a schematic diagram illustrating a smart device including a display device according to an embodiment.

Referring to FIG. 28, a display device 10 according to an embodiment may be applied to a smart watch 2 as one of smart devices.

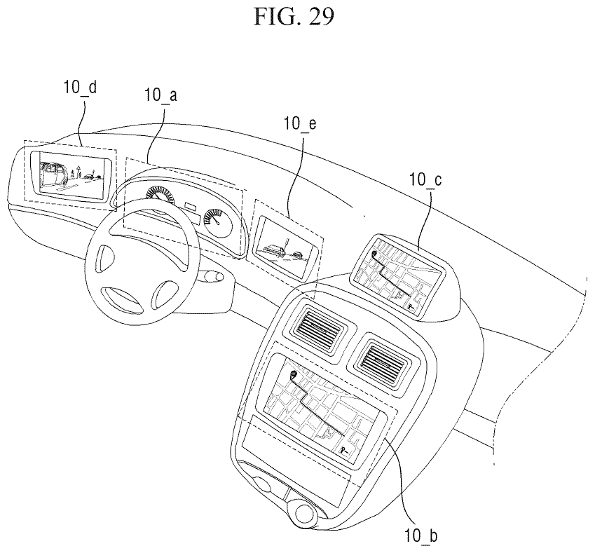

FIG. 29 is a schematic diagram illustrating a vehicle including a display device according to an embodiment. FIG. 29 illustrates a vehicle in which display devices according to an embodiment are provided.

Referring to FIG. 29, the display devices 10_a, 10_b, and 10_c according to an embodiment may be applied to the dashboard of the vehicle, applied to the center fascia of the vehicle, or applied to a CID (Center Information Display) disposed on the dashboard of the vehicle. Further, each of the display devices 10_d and 10_e according to an embodiment may be applied to each room mirror display that replaces each of side-view mirrors of the vehicle.

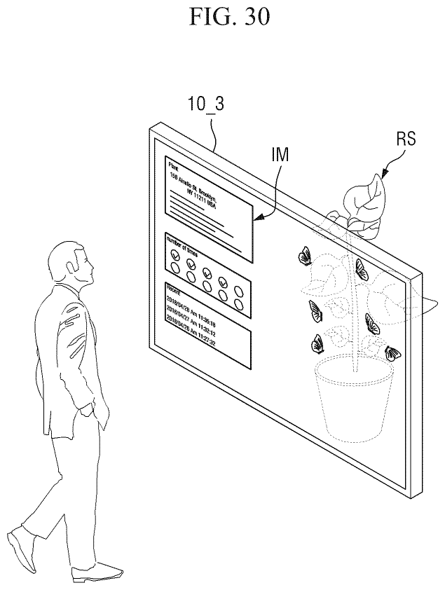

FIG. 30 is a schematic diagram illustrating a transparent display device including a display device according to an embodiment.

Referring to FIG. 30, a display device according to an embodiment may be applied to a transparent display device. The transparent display device may transmit light while displaying an image IM thereon. Therefore, a user located in front of the transparent display device may not only view the image IM displayed on the display device 10, but also view an object RS or a background located behind the transparent display device. In case that the display device 10 is applied to the transparent display device, the first substrate 110 of the display device 10 shown in FIG. 7 may include a light transmitting portion that may transmit light or may be made of a material that may transmit light.

In concluding the detailed description, those skilled in the art will appreciate that many variations and modifications can be made to the embodiments without substantially departing from the principles of the disclosure. Therefore, the disclosed embodiments of the disclosure are used in a generic and descriptive sense only and not for purposes of limitation.

What is claimed is:

1. A display device, comprising:
a substrate including a pixel circuit;
a pixel electrode connected to the pixel circuit;
an insulating layer disposed on the pixel electrode;
a through electrode penetrating the insulating layer and connecting to the pixel electrode;
a bottom bonding electrode and an upper bonding electrode sequentially disposed on the through electrode and the insulating layer; and
a light emitting element disposed on the upper bonding electrode, wherein
the through electrode has a groove whose upper surface is concave downward,
a lower surface of the bottom bonding electrode follows a surface profile of the insulating layer and the through electrode disposed below, and an upper surface is flat, and
the bottom bonding electrode includes an oxide layer.

2. The display device of claim 1, wherein
the lower surface of the bottom bonding electrode has a downwardly convex protrusion corresponding to a concave groove of the through electrode, and
the upper surface is flat.

3. The display device of claim 1, wherein
the bottom bonding electrode includes a first bottom bonding electrode formed of different materials and a second bottom bonding electrode disposed on the first bottom bonding electrode, and
the oxide layer is disposed between layers of the first bottom bonding electrode.

4. The display device of claim 3, wherein the first bottom bonding electrode and the second bottom bonding electrode are made of a material selected from the group consisting of titanium (Ti), nickel (Ni), platinum (Pt), tin (Sn), gold (Au), aluminum (Al), and tungsten (W).

5. The display device of claim 2, wherein an upper surface and a lower surface of the upper bonding electrode are flat.

6. The display device of claim 5, wherein the upper bonding electrode is formed of one or more layers.

7. The display device of claim 1, further comprising a barrier film surrounding a side surface of the through electrode.

8. The display device of claim 7, wherein the barrier film includes a material that prevents movement of metal ions forming the through electrode.

9. The display device of claim 1, wherein the upper bonding electrode and the bottom bonding electrode protrude outside the light emitting element.

10. The display device of claim 1, further comprising:
a first insulating layer that surrounds sides of the light emitting element and the upper bonding electrode;
a reflective layer disposed on a side of the light emitting element;
a second insulating layer surrounding sides of the light emitting element and the upper bonding electrode on the reflective layer and the first insulating layer; and
a common electrode disposed on an upper portion of the light emitting element.

11. The display device of claim 10, further comprising:
a lens-type optical structure on a light emitting element layer including the light emitting element and the common electrode.

12. A method of manufacturing a display device, comprising:
providing a backplane substrate including a pixel electrode connected to a pixel circuit and an insulating layer disposed on the pixel electrode;
forming a through electrode that penetrates the insulating layer and is connected to the pixel electrode;
planarizing top surfaces of the insulating layer and the through electrode;
applying a conductive bonding material to a top surface of the through electrode;
planarizing the conductive bonding material to form an oxide layer on the top surface of the through electrode;
forming a bottom bonding electrode layer by additionally applying a conductive bonding material on a conductive bonding material on which the oxide layer is formed;
providing a base substrate having an upper bonding electrode layer and a plurality of semiconductor layers;
bonding the base substrate and the backplane substrate and removing the base substrate; and
forming a plurality of light emitting elements by etching the plurality of semiconductor layers.

13. The method of claim 12, wherein the planarizing of the top surfaces of the insulating layer and the through electrode, the planarizing of the conductive bonding material to form an oxide layer on the top surface of the through electrode, and the removing of the base substrate include a chemical mechanical polishing (CMP) process.

14. The method of claim 12, wherein the planarizing of the top surfaces of the insulating layer and the through electrode include forming a downwardly concave groove on the through electrode.

15. The method of claim 14, wherein
a lower surface of the bottom bonding electrode layer has a downwardly convex protrusion corresponding to a concave groove of the through electrode, and
an upper surface of the bottom bonding electrode is flat.

16. The method of claim 12, further comprising:
forming a bonding electrode by etching the bottom bonding electrode layer and the upper bonding electrode layer.

17. The method of claim 16, wherein the forming of the bottom bonding electrode includes:
additionally applying a conductive bonding material on the conductive bonding material on which the oxide layer is formed,
forming a first bottom bonding electrode layer by additionally applying first conductive bonding material, and
forming a second bottom bonding electrode layer on the first bottom bonding electrode layer by applying a second conductive bonding material different from the first conductive bonding material.

18. The method of claim 12, further comprising:
forming an insulating layer and a reflective layer surrounding a side surface of the light emitting element.

19. The method of claim 17, further comprising:
forming a common electrode on the light emitting elements.

20. The method of claim 19, further comprising:
forming a lens-type optical structure on the light emitting element layer including the light emitting elements and the common electrode.
